(19) United States
(12) Patent Application Publication
(10) Pub. No.: US 2010/0108565 A1
(43) Pub. Date: May 6, 2010

(54) Wafer container having the snap-fitting restraint module

(76) Inventors: Pao-Yi Lu, Shulin City (TW); Chin-Ming Lin, Shulin City (TW); Kuan-Lun Pan, Shulin City (TW)

Correspondence Address: SINORICA, LLC, 2275 Research Blvd., Suite 500, ROCKVILLE, MD, 20850, US

(21) Appl. No.: 12/326,280

(22) Filed: Dec. 2, 2008

(30) Foreign Application Priority Data
Nov. 4, 2008 (TW) 097142441

(51) Int. Cl. H01L 21/673; B65D 51/26

(52) U.S. Cl. 206/711; 206/587; 220/694

(57) ABSTRACT

A wafer container includes a container body, the internal of which is disposed with a plurality of slots for supporting a plurality of wafers and an opening is formed on one sidewall of which for importing and exporting said plurality of wafers, and a door with an inner surface, which is joined with opening of the container body with the inner surface for protecting the plurality of wafers in the container body, the characteristic in that: at least one restraint module is disposed on the inner surface of the door, the restraint module including a base which is disposed with a plurality of restraints arranged at intervals and an opening, and a snap-fitting piece is disposed on the inner surface of the door for snap-fitting the restraint module by passing the snap-fitting piece through the opening of the base of restraint module and rotating the restraint to an angle.

### BACKGROUND OF THE INVENTION

1. Field of the Invention

The present field of the invention is related to a wafer container, and more particularly, to a structure for fixing a wafer restraint module on the door of the wafer container.

2. Description of the Prior Art

The semiconductor wafers are transferred to different stations to apply the various processes in the required equipments. A sealed container is provided for automatic transfer to prevent the pollution from occurring during transferring process. FIG. 1 shows the views of wafer container of the conventional prior art. The wafer container is a front opening unified pod (FOUP) which includes a container body 10 and a door 20. The container body 10 is disposed with a plurality of slots 11 for horizontally placing a plurality of wafers, and an opening 12 is located on a sidewall of the container body 10 for importing and exporting. Further, the door 20 includes an outer surface 21 and an inner surface 22, in which the door 20 is joined with the opening 12 of the container body 10 via inner surface 22 to protect the plurality of wafers within the container body 10. Furthermore, at least one latch hole 23 is disposed on the outer surface 21 of the door 20 for opening or closing the wafer container. According to the aforementioned, due to that the wafer is placed in the container body 10 horizontally, thus, the FOUP needs a wafer restraint component to prevent the wafer from displacement or from movement toward the opening 12 of container body 10 occurring during the wafer transportation due to vibration.

FIG. 2 is a view of a front opening unified pod (FOUP) as described in U.S. Pat. No. 6,736,268. As shown in FIG. 2, the inner surface 22 of the door 20 is disposed with a recess 24 and the recess 24 is extended from the top 221 of the inner surface 22 to the bottom 222, and is located between two latch components 230 (inside of the door 20). Two wafer restraint modules 100 are further disposed in the recess 24. The wafer restraint modules 100 include a plurality of wafer contact heads (not shown in Figure) to sustain corresponding wafers so as to prevent the wafer from displacement or movement toward the door opening due to vibration occurring in the wafer transportation procedure. However, the above-mentioned wafer restraint modules 100 are disposed in the recess 24 of the inner surface 22 of the door 20, and the wafer is merely attached to the inner surface 22 of the door 20 or the wafer is partially settled down within the recess 24, and thus the length between the front side and the back side of the FOUP can not be effectively shortened.

Then, referring to FIG. 3, which is a sectional view of a wafer restraint component of prior art in the process of restricting the wafer. The wafer restraint component 110 is disposed in the opening 0 on the inner surface 22 beside the recess 24 of the door 20, wherein a plurality of right-left symmetrical spring arms 120 of wafer restraint component 110 are used for respectively sustaining each wafer to prevent the wafer from displacement or movement toward the door opening due to vibration occurring in the wafer transportation procedure. However, in the aforementioned structure, a row of openings O need to be further disposed on two sides of the inner surface 22 of the door 20, and a bolt 120P and a round-shaped ring are to be further disposed on the wafer restraint component 110 for the wafer restraint component 110 to be insertingly disposed and thus fixed in the opening O. Such structure turns out to be complex in terms of manufacturing and assembling, and not only does the disposition of a plurality of openings O lead easily to poor air tightness but the plurality of openings O also easily become dead spots in the cleaning and drying process of the door 20.

### SUMMARY OF THE INVENTION

In wafer container of the prior art, the design of its wafer restraint component or wafer restraint module makes it unachievable for the size of wafer container to be reduced, hard for dust particles to be cleaned up, and easy for wafers to come loose. One objective of the present invention is thus to provide a front opening unified pod (FOUP) with wafer restraint module, in which the wafer restraint module is disposed on the platforms on two sides of the recess of inner surface of the door for wafer to be fully and effectively filled in the recess to shorten the length between the front side and the back side of the FOUP.

Another objective of the present invention is to provide a front opening unified pod (FOUP) with wafer restraint module, wherein the wafer restraint module can be easily and stably installed or fixed on the platforms on two sides of the recess so that the disposition of two rows of openings on the inner surface of the door that will cause difficulties in manufacturing and assembling process is not needed.

Still another objective of the present invention is to provide a front opening unified pod (FOUP) with wafer restraint module, in which the wafer restraint module is disposed on the platforms on two sides of the recess of inner surface of the door; therefore, dust particles generated due to friction between wafer restraint component and wafer can be gathered in the corner of recess and can be easily cleaned up when cleaning the wafer container without needing to remove the wafer restraint module.

According to above objectives, the present invention provides a front opening unified pod (FOUP), which includes a container body and a door. A plurality of slots are disposed in the container body for sustaining a plurality of wafers, and an opening is formed on one sidewall of the container body for importing and exporting the plurality of wafers. The door includes an outer surface and an inner surface; the door joins with the opening of container body via its inner surface for protecting the plurality of wafers in the container body. The characteristic of front opening unified pod (FOUP) in that: at least one restraint module is disposed on the inner surface of the door, the restraint module including a base which is disposed with a plurality of restraints arranged at intervals and an opening, and a snap-fitting piece is disposed on the inner surface of the door for snap-fitting the restraint module, wherein the snap-fitting piece snap-fits the base of wafer restraint module and fixes the wafer restraint module on the inner surface of the door by passing the snap-fitting piece through the opening of the base of wafer restraint module and rotating the wafer restraint module to an angle.

Moreover, the base of the aforementioned restraint module further includes a plurality of subsidiary openings for being fixed to the snap pillar of the inner surface of the door via snapping on the snap pillar to achieve better fixing effect, allowing the restraint module to be stably and fixedly installed or fixed on the inner surface of the door.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a view of a front opening unified pod (FOUP) of the prior art;

FIG. 2 is a view of the door of a front opening unified pod (FOUP) of the prior art;

FIG. 3 is a sectional view of a wafer restraint component of the prior art in the process of restricting the wafer;

FIG. 4 is a view of a front opening unified pod (FOUP) of the present invention;

FIG. 5 is a view of wafer restraint module of a front opening unified pod (FOUP) of the present invention in the process of contacting the wafer;

FIG. 6A and FIG. 6B are views of wafer restraint module of front opening unified pod (FOUP) of the present invention being not yet fixed to and already fixed to the inner surface of the door;

FIG. 7 is a view of the arrangement of the plurality of restraint components of wafer restraint module of the present invention at intervals;

FIG. 8A to FIG. 8C are views of another design of opening of the base of wafer restraint module of the present invention;

FIG. 9 is a view of another kind of arrangement of the plurality of restraint components of wafer restraint module of the present invention at intervals;

FIG. 10 is a view of restraint components in another kind of arrangement of the present invention in the process of contacting the wafer;

FIG. 11 is a view of another kind of front opening unified pod (FOUP) of the present invention;

FIG. 12A is a view of wafer restraint module of another kind of front opening unified pod (FOUP) of the present invention starting to contact the wafer; and

FIG. 12B is a view of wafer restraint module of another kind of front opening unified pod (FOUP) of the present invention completely contacting the wafer.

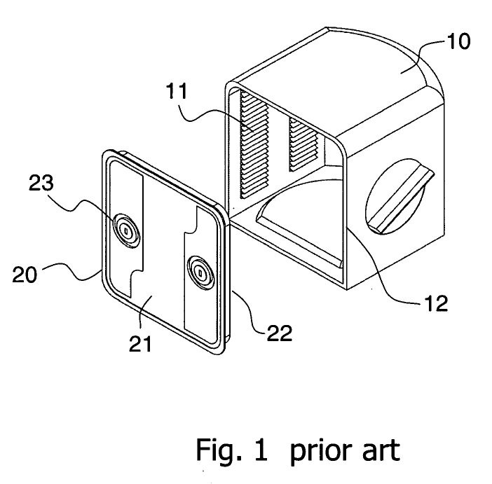

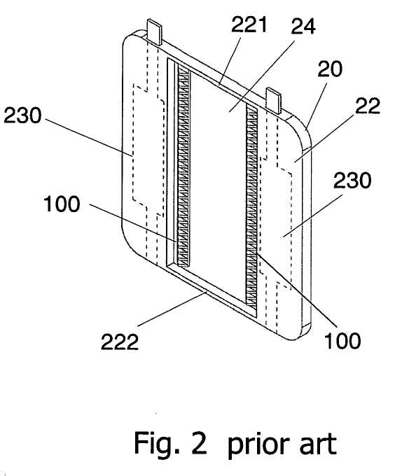

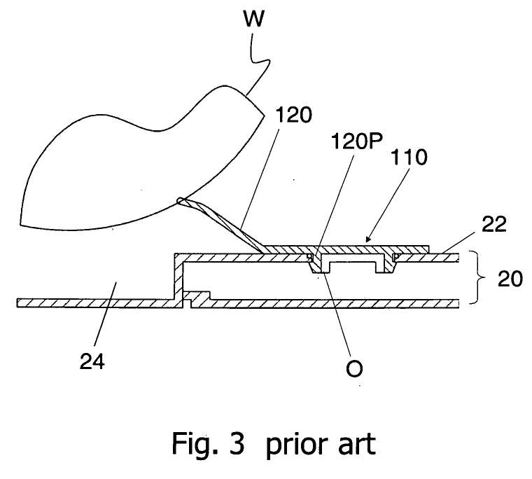

### DESCRIPTION OF THE PREFERRED EMBODIMENT

In order to disclose the skills applied in, the objectives of, and the effects achieved by the present invention in a more complete and clearer manner, preferred embodiments are herein described below in detail with related drawings disclosed for reference.

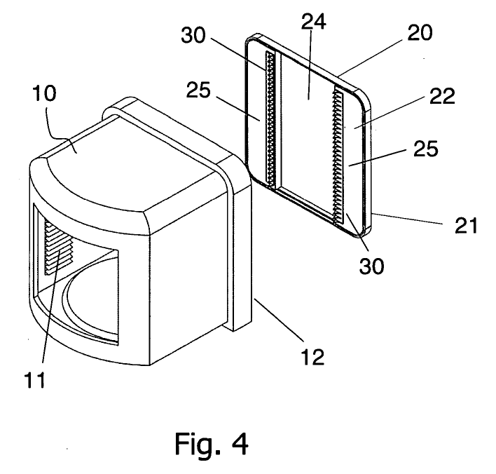

First, referring to FIG. 4, which is a view of a front opening unified pod (FOUP) of the present invention. The front opening unified pod (FOUP) includes a container body 10 and a door 20. A plurality of slots 11 are disposed in the container body 10 for sustaining a plurality of wafers, and an opening 12 is formed on one sidewall of the container body 10 for importing and exporting the plurality of wafers. The door 20 includes an outer surface 21 and an inner surface 22, and in the central part of the inner surface 22 of the door 20 is disposed with a recess 24. The recess 24 further divides the inner surface 22 of the door 20 into two platforms 25, and a wafer restraint module 30 is further disposed on each of the two platforms 25.

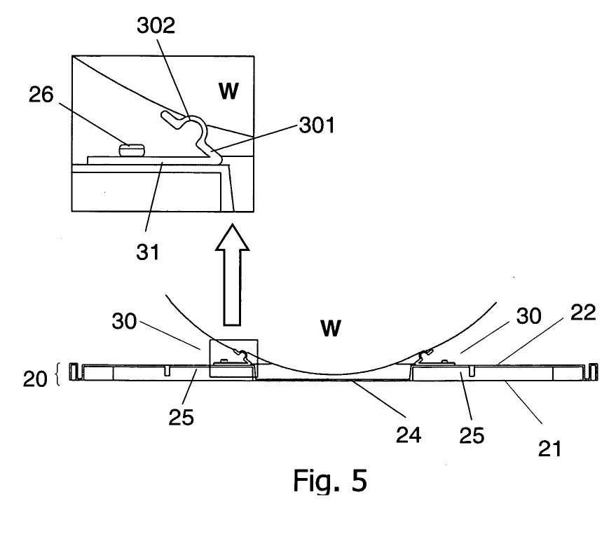

And as shown in FIG. 5, when the door 20 closes the container body 10, since no other components are disposed in the recess 24, the recess 24 can be used for accommodating a plurality of wafers in the container body 10 to shorten the length between the front side and the back side of the FOUP. And the wafer restraint modules 30 on the platforms 25 can also push each wafer in the container body 10 to a fixed position and restrict it from shaking. Since the wafer restraint module 30 is not placed in the recess 24, thus when the process of cleaning wafer container is performed, dust particles can be easily cleaned up with no need to remove the wafer restraint module 30. Moreover, a latch component (not shown in Figure) is further disposed in each of the two platforms 25 of the present invention, and each latch component forms latch hole on corresponding outer surface 21 for facilitating the closing or opening of the door 20.

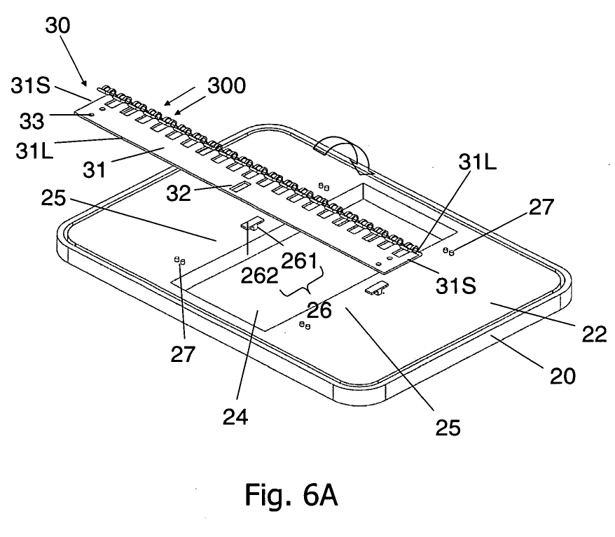

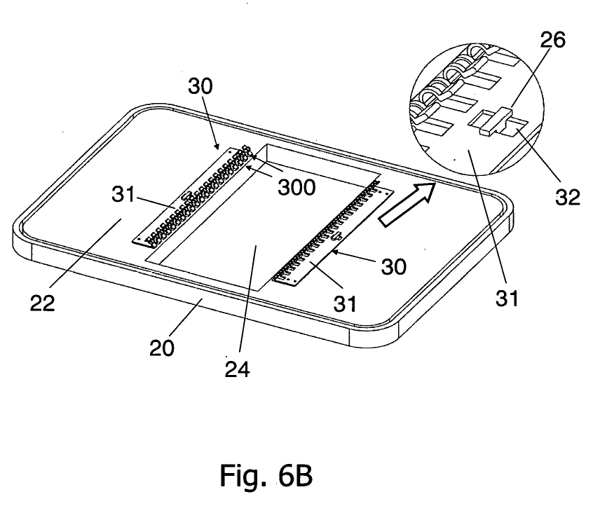

Referring to FIG. 6A and FIG. 6B, which are views of wafer restraint module of the front opening unified pod (FOUP) in FIG. 4 being not yet fixed to and already fixed to the inner surface of the door. The wafer restraint modules 30 of the present invention are located on the two platforms 25 on two sides of the recess 24. The wafer restraint module 30 includes a base 31, and the base 31 includes two longer sides 31L and two shorter sides 31S, near one of the longer sides 31L are a plurality of restraint components 300 disposed at intervals. Moreover, the base 31 further includes an opening 32, and the shape of opening 32 can be rectangular, rhomboid, or oval; a snap-fitting piece 26 with protruding portion 261 and snap-fitting portion 262 is disposed on the inner surface 22 of the door 20, one end of protruding portion 261 being fixed on the inner surface 22 of the door 20 and the other end (or free end) being connected to the snap-fitting portion 262, the shape or size of snap-fitting portion 262 being the same as those of opening 32 of base 31, being able to be rectangular, rhomboid, or oval. Therefore, the snap-fitting piece 26 can pass through the opening 32 of the base 31 of wafer restraint module 30 and after the wafer restraint module 30 is rotated to an angle (for example, rotated 90 degrees clockwise in FIG. 6A and FIG. 6B), the snap-fitting piece 26 snap-fits the base 31 of wafer restraint module 30 and fixes the wafer restraint module 30 on the inner surface 22 of the door 20.

And as shown in FIG. 6A, the base 31 of wafer restraint module 30 further includes a plurality of subsidiary openings 33, and on the inner surface 22 of door 20 corresponding to the plurality of subsidiary openings 33 a plurality of snap pillars 27 are further included, the diameter of free end of snap pillars 27 being slightly longer than the diameter of subsidiary openings 33. Therefore when the snap-fitting piece 26 snap-fits the base 31, the subsidiary openings 33 can be further snapped on the lower rim of free end of snap pillars 27 for reinforcing the fixation of wafer restraint module 30 and its base 31 on the inner surface 22 of the door 20.

When the aforementioned snap-fitting piece 26 and snap pillars 27 on the inner surface 22 of the door 20 snap-fit the opening 32 and subsidiary opening 33 on the base 31, as shown in FIG. 6B, the plurality of restraint components 300 of wafer restraint module 30 on two sides of recess 24 arranged at intervals are in couple so that each corresponding restraint component 300 can contact a wafer to prevent wafer in the container body from moving toward the direction of the opening during transportation process.

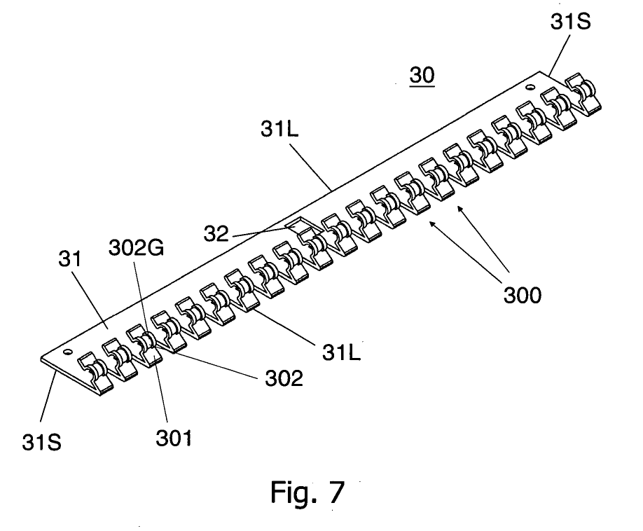

Referring to FIG. 7, which is a view of the arrangement of the plurality of restraint components of wafer restraint module of the present invention at intervals. As shown in FIG. 5 and FIG. 7, the plurality of restraint components 300 of the wafer restraint module 30 arranged at intervals are a plurality of suspended arms 301 formed by the extension of one of the longer sides 31L of the base 31 that is nearer to the recess 24, a semicircle-like protruding portion 302 being formed between each suspended arm 301 and its free end, and the protruding portion 302 being disposed with a guide notch 32G for contacting wafer in the container body. There is gap between neighboring restraint components 300 for the restraint components 300 to correspond to wafers in the container body 10. And the surface of guide notch 32G that contacts wafer can be coated with a wear-resisting material, such as polyetheretherketone (PEEK), to reduce friction and dust particles generated. Moreover, the width of guide notch 32G can be equal to the thickness of wafer for the wafer to sink into the guide notch 32G without moving up and down. Apparently, an angle is formed between the aforementioned base 31 and the suspended arm 301, and the degree of angle can be 10˜60 degrees.

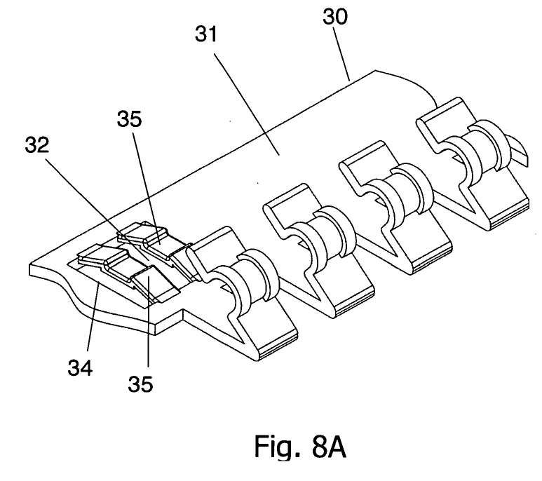

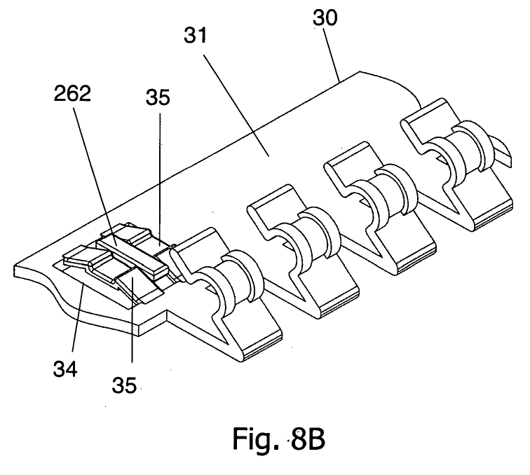

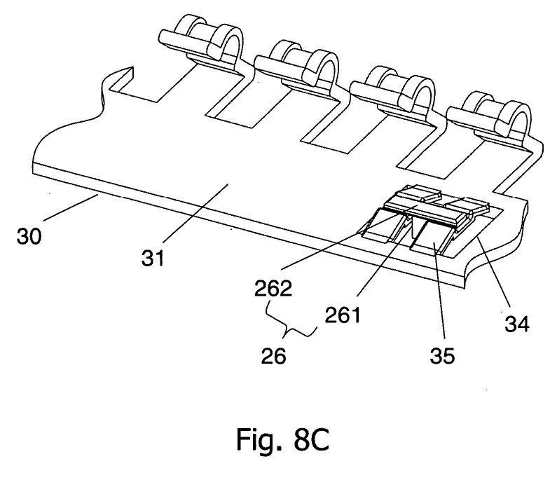

Then, referring to FIG. 8A to FIG. 8C, which are views of another design of opening of the base of wafer restraint module of the present invention. The base 31 of wafer restraint module 30 includes a rectangular mounting hole 34, and in the rectangular mounting hole 34 are disposed with a plurality of elastic pieces 35 for an opening 32 to be formed among the elastic pieces 35. And as shown in FIG. 6A, a snap-fitting piece 26 is disposed on the inner surface 22 of the door 20, and the structure of snap-fitting piece 26 includes protruding portion 261 and snap-fitting portion 262. The shape and size of the aforementioned snap-fitting portion 262 and the opening 32 among elastic pieces 35 are the same, being in the shape of a rectangle. Therefore, the snap-fitting piece 26 can pass through the opening 32 of the base 31 of wafer restraint module 30 and after the wafer restraint module 30 is rotated to an angle, 90 degrees clockwise or 90 degrees counterclockwise for example, the snap-fitting piece 26 snap-presses the elastic pieces 35 and fixes the wafer restraint module 30 on the inner surface 22 of the door 20.

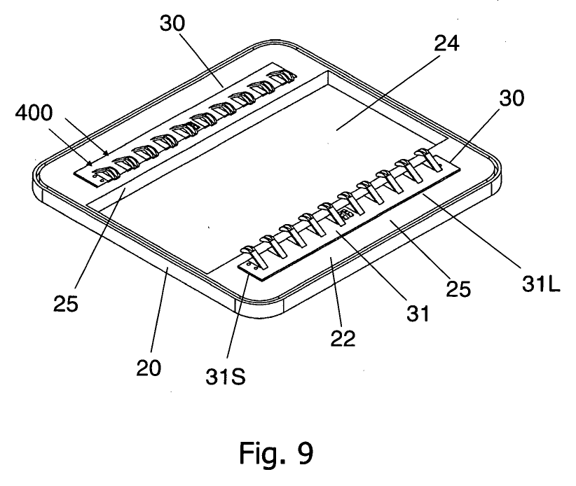

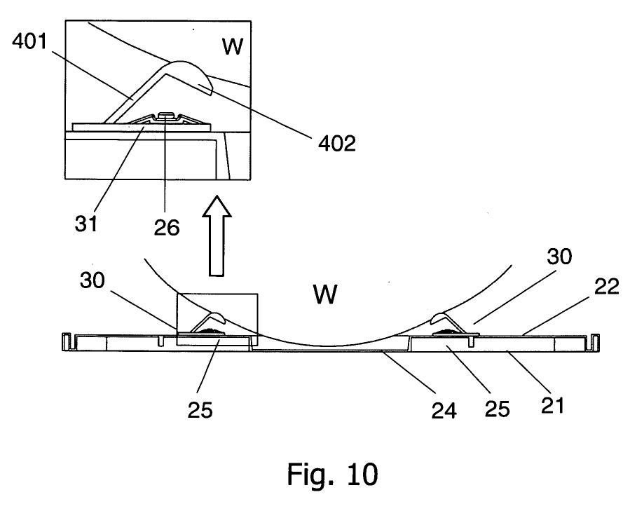

Then, referring to FIG. 9 and FIG. 10, which are views of another kind of arrangement of the plurality of restraint components of wafer restraint module of the present invention at intervals. The plurality of restraint components 400 arranged at intervals are a plurality of supporting arms 401 formed by one longer side 31L of the base 31 bending toward the recess 24, and a sustaining portion 402 bending downward is formed on free end of each supporting arm 401 for contacting wafer in the container body. In one preferred embodiment of the present invention, the angle formed by the base 31 and the bend of supporting arm 401 is an acute angle, the degree of which can be determined according to the position of the wafer restraint module 30 disposed on the platform 25; for example, the angle can be 10˜60 degrees. Furthermore, in another preferred embodiment of the present invention, a quasi-V-shaped guide notch (not shown in Figure) is further formed on the sustaining portion 402 for allowing the wafer to be smoothly guided into the guide notch when being contacted by the sustaining portion 402 of restraint component 400 without moving up and down. In addition, in order to reduce friction for the wafer, the surface of guide notch that contacts wafer can be coated with a wear-resisting material, such as polyetheretherketone (PEEK).

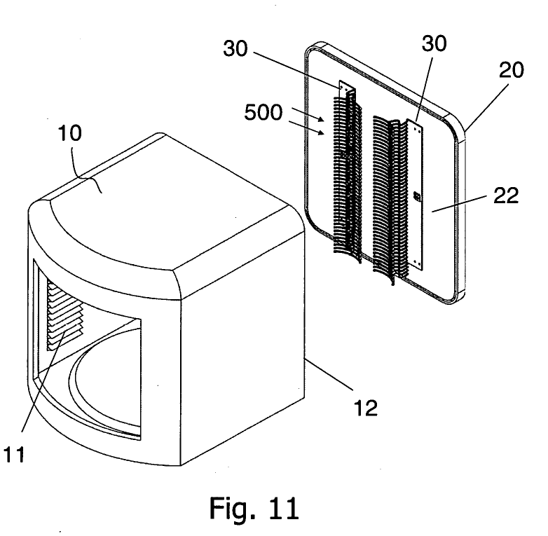

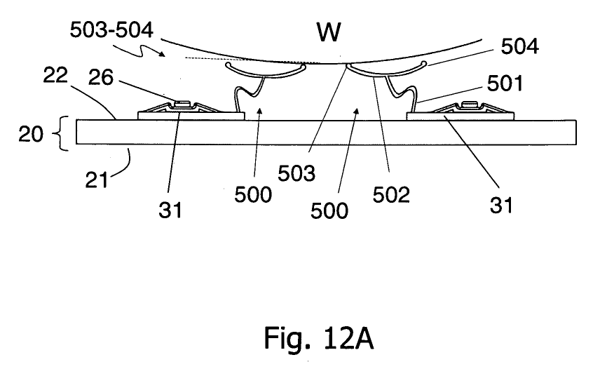

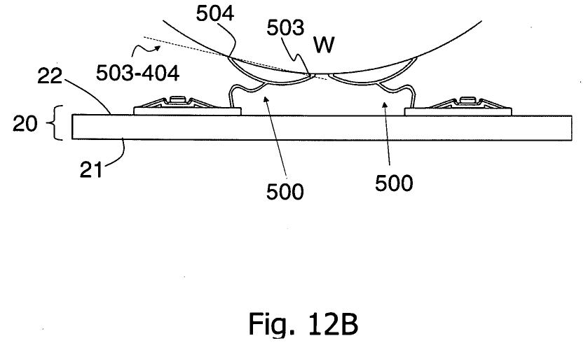

Then, referring to FIG. 11, which is a view of another front opening unified pod (FOUP) of the present invention, and FIG. 12A and FIG. 12B, which are views of wafer restraint module of the front opening unified pod (FOUP) in FIG. 11 starting to contact the wafer and completely contacting the wafer. The front opening unified pod (FOUP) includes a container body 10 and a door 20, and the difference between this front opening unified pod (FOUP) and the front opening unified pod (FOUP) in FIG. 4 is in that: the inner surface 22 of the door 20 does not include a recess. Therefore, the wafer restraint modules 30 are located on two sides of central part of inner surface 22, wherein the wafer restraint module 30 includes a base 31 and on the base 31 is disposed with an opening 32 and a plurality of subsidiary openings 33 for the snap-fitting piece 26 and a plurality of snap pillars 27 on the inner surface 22 of the door 20 to fix the wafer restraint module 30 on the inner surface 22 of the door 20 (as shown in FIG. 6A). And each of the plurality of restraint components 500 on the wafer restraint module 30 includes a base portion 501 with one end fixed on the base 31 and the other end connected to a bent arm 502, wherein the bent arm 502 includes a first contact end 503 and a second contact end 504.

The base portion 501 of each restraint component 500 as described above can be an elastic structure (for example: thermal-elastic plastic), and when the door 20 and the container body 10 are not yet or about to be joined with each other, the connecting line between first contact end 503 and second contact end 504 of restraint component 500 (503-504) is parallel to the inner surface 22 of the door 20. Meanwhile, the wafer first contacts the first contact head 503, and when the wafer contact the first contact head 503, the base portion 501 deforms and levers the bent arm 502 for the other contact end of the bent arm 502, i.e. second contact end 504, to contact wafer sequentially. Meantime, as shown in FIG. 12B, the door 20 is joined with the container body 10 and an included angle is formed between the connecting line between the first contact end 503 and the second contact end 504 of restraint component 500 (503-504) and the inner surface 22 of the door 20. Apparently, each restraint component 500 contacts wafer with two contact ends, not only preventing the wafer from moving toward the center of the opening but also limiting the wafer to move toward two sides of the opening. Therefore, when the wafer restraint module 30 contacts wafer, a resultant forces pushing only toward center point of wafer can be generated without causing the wafer to shake from side to side. Moreover, the first contact end 503 and the second contact end 504 can each include a recess for the wafer to sink into the recess without moving up and down.

Of course, the wafer restraint module 30 with a plurality of restraint components 500 can be used in the door 20 without recess 24, and can also be used in the door 20 with recess 24. And the aforementioned wafer restraint module 30 with a plurality of restraint components 300 and 400 can also be used in the door 20 without recess 24. In addition, the structure of wafer restraint modules 30 used in the present invention can be an integrated structure to reduce the manufacturing cost.

While the invention has been described by way of examples and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A wafer container including a container body that having a plurality of slots therein for placing a plurality of wafers and having an opening formed on a sidewall of said wafer container for exporting said plurality of wafers or importing said plurality of wafers, and a door with an outer surface and an inner surface, said door joining with said opening of said container body via said inner surface for protecting said plurality of wafers in said container body, the characteristic in that:
at least a restraint module is disposed on said inner surface of said door, said restraint module including a base and a plurality of restraint components arranged at intervals being disposed on said base, wherein said base of said restraint module further includes an opening and a snap-fitting piece is further disposed on said inner surface of said door, said snap-fitting piece snap-fits said base of said wafer restraint module and fixes said wafer restraint module on said inner surface of said door by passing said snap-fitting piece through said opening of said base of said wafer restraint module and rotating said wafer restraint module to an angle.

2. The wafer container according to claim 1, wherein shape of said opening of said base is selected from the group consisting of: rectangular, rhomboid, and oval.

3. The wafer container according to claim 1, wherein said snap-fitting piece is composed of a protruding portion and a snap-fitting portion located at free end of said protruding portion.

4. The wafer container according to claim 3, wherein shape of said snap-fitting portion of said snap-fitting piece is selected from the group consisting of: rectangular, rhomboid, and oval.

5. The wafer container according to claim 1, wherein said base of said restraint module further includes a plurality of subsidiary openings, and on said inner surface of said door corresponding to said plurality of subsidiary openings a plurality of snap pillars are further included for said base of said restraint module to be snapped on and thus fixed to said inner surface of said door.

6. The wafer container according to claim 1, wherein said plurality of restraint components arranged at intervals are a plurality of suspended arms formed by extension of one longer side of said base, and a semicircle-like protruding portion is formed between each suspended arm and its free end, said protruding portion being disposed with a guide notch for contacting said plurality of wafers in said container body.

7. The wafer container according to claim 1, wherein said plurality of restraint components arranged at intervals are a plurality of supporting arms formed by one longer side of said base bending toward central part of said inner surface of said door, and a sustaining portion bending downward is formed on free end of each supporting arm for contacting said plurality of wafer in said container body.

8. A wafer container including a container body that having a plurality of slots therein for placing a plurality of wafers and having an opening formed on a sidewall of said wafer container for exporting said plurality of wafers or importing said plurality of wafers, and a door with an outer surface and an inner surface, said door joining with said opening of said container body via said inner surface for protecting said plurality of wafers in said container body, the characteristic in that:
a recess is disposed on said inner surface of said door and located between two platforms, and on each of said two platforms near edge of said recess is respectively disposed a restraint module, each of said restraint module including a base and a plurality of restraint components arranged at intervals being disposed on said base, wherein said base of said restraint module further includes an opening and a snap-fitting piece is further disposed on said inner surface of said door, said snap-fitting piece snap-fits said base of said wafer restraint module and fixes said wafer restraint module on said inner surface of said door by passing said snap-fitting piece through said opening of said base of said wafer restraint module and rotating said wafer restraint module to an angle.

9. The wafer container according to claim 8, wherein shape of said opening of said base is selected from the group consisting of: rectangular, rhomboid, and oval.

10. The wafer container according to claim 8, wherein said snap-fitting piece is composed of a protruding portion and a snap-fitting portion located at free end of said protruding portion.

11. The wafer container according to claim 10, wherein shape of said snap-fitting portion of said snap-fitting piece is selected from the group consisting of: rectangular, rhomboid, and oval.

12. The wafer container according to claim 8, wherein said base of said restraint module further includes a plurality of subsidiary openings, and on said inner surface of said door corresponding to said plurality of subsidiary openings a plurality of snap pillars are further included for said base of said restraint module to be snapped on and thus fixed to said inner surface of said door.

13. The wafer container according to claim 8, wherein said plurality of restraint components arranged at intervals are a plurality of suspended arms formed by extension of one longer side of said base, and a semicircle-like protruding portion is formed between each suspended arm and its free end, said protruding portion being disposed with a guide notch for contacting said plurality of wafers in said container body.

14. The wafer container according to claim 8, wherein said plurality of restraint components arranged at intervals are a plurality of supporting arms formed by one longer side of said base bending toward said recess, and a sustaining portion bending downward is formed on free end of each supporting arm for contacting said plurality of wafer in said container body.

15. A wafer container including a container body that having a plurality of slots therein for placing a plurality of wafers and having an opening formed on a sidewall of said wafer container for exporting said plurality of wafers or importing said plurality of wafers, and a door with an outer surface and an inner surface, said door joining with said opening of said container body via said inner surface for protecting said plurality of wafers in said container body, the characteristic in that:
a recess is disposed on said inner surface of said door and located between two platforms, and on each of said two platforms near edge of said recess is respectively disposed a restraint module, each of said restraint module including a base and a plurality of restraint components arranged at intervals being disposed on said base, said base of said restraint module including a rectangular mounting hole, said rectangular mounting hole being disposed with a plurality of elastic pieces for an opening to be formed among the elastic pieces, and a snap-fitting piece being further disposed on said inner surface of said door, said snap-fitting piece snap-presses said plurality of elastic pieces and and fixes said wafer restraint module on said inner surface of said door by passing said snap-fitting piece through said opening formed among the elastic pieces and rotating said wafer restraint module to an angle.

16. The wafer container according to claim 15, wherein said snap-fitting piece is composed of a protruding portion and a snap-fitting portion located at free end of said protruding portion.

17. The wafer container according to claim 16, wherein said snap-fitting portion is in the shape of a rectangle.

18. The wafer container according to claim 15, wherein said base of said restraint module further includes a plurality of subsidiary openings, and on said inner surface of said door corresponding to said plurality of subsidiary openings a plurality of snap pillars are further included for said base of said restraint module to be snapped on and thus fixed to said inner surface of said door.

19. The wafer container according to claim 15, wherein said plurality of restraint components arranged at intervals are a plurality of suspended arms formed by extension of one longer side of said base, and a semicircle-like protruding portion is formed between each suspended arm and its free end, said protruding portion being disposed with a guide notch for contacting said plurality of wafers in said container body.

20. The wafer container according to claim 15, wherein said plurality of restraint components arranged at intervals are a plurality of supporting arms formed by one longer side of said base bending toward said recess, and a sustaining portion bending downward is formed on free end of each supporting arm for contacting said plurality of wafer in said container body.
